(19) United States
(12) Patent Application Publication
(10) Pub. No.: US 2012/0306063 A1
(43) Pub. Date: Dec. 6, 2012

(54) HIGH-FREQUENCY MODULE MANUFACTURING METHOD

(75) Inventors: Jun'ichi KIMURA, Osaka (JP); Tomohide Ogura, Mie (JP); Takayuki Hiruma, Osaka (JP); Misao Kanba, Mie (JP); Masahisa Nakaguchi, Mie (JP); Motoyoshi Kitagawa, Mie (JP)

(73) Assignee: Panasonic Corporation, Osaka (JP)

(21) Appl. No.: 13/587,297

(22) Filed: Aug. 16, 2012

Related U.S. Application Data
(63) Continuation of application No. PCT/JP2011/000719, filed on Feb. 9, 2011.

(30) Foreign Application Priority Data
Feb. 19, 2010 (JP) 2010-034461

(51) Int. Cl. H01L 21/56; H01L 23/28; H01L 21/78

(52) U.S. Cl. 257/659; 438/127; 438/113; 257/E21.502; 257/E21.599; 257/E23.116

(57) ABSTRACT

In a method of manufacturing a high-frequency module, a resin substrate with a high frequency circuit including an electronic component mounted thereon is placed so that the electronic component faces a resin bath. A resin which is in a non-flowable state in the resin bath is softened until the resin becomes flowable, and air in space formed between the resin substrate and the resin is sucked. The resin substrate is brought into contact with a liquid surface of the resin. The resin is pressurized and allowed to flow into a gap between the resin substrate and the electronic component. The resin is cured so that a resin portion is formed on the resin substrate. A shield metal film is formed on a surface of the resin portion.

This application is a Continuation of International Application No. PCT/JP11/000,719, filed on Feb. 9, 2011, claiming priority of Japanese Patent Application No. 2010-034461, filed on Feb. 19, 2010, the entire contents of each of which are hereby incorporated by reference.

### TECHNICAL FIELD

The present disclosure relates to a method for manufacturing a high-frequency module in which an electronic component mounted on a resin substrate is covered by a resin, and a circuit formed of the electronic component is shielded.

### BACKGROUND ART

A conventional high-frequency module will be described with reference to the drawings. FIG. 10 is a cross sectional view of a conventional high-frequency module.

Printed circuit board 2 is made of a thermosetting resin. Electronic component 3 is mounted on an upper surface of printed circuit board 2. Here, electronic component 3 is a semiconductor device or the like, and the semiconductor device and printed circuit board 2 are connected to each other by wire bonding. Components other than electronic component 3 may be mounted on the upper surface of printed circuit board 2. Electronic component 3 forms a high-frequency circuit. Resin portion 4 is formed on the upper surface of printed circuit board 2, and electronic component 3 is buried in resin portion 4. Connection pattern 5 connected to the ground of the high-frequency circuit is formed in a peripheral end portion of the upper surface of printed circuit board 2.

Shield film 6 is a thick film conductor. Shield film 6 is formed to cover an upper surface and side surfaces of resin portion 4 and a part of a side surface of printed circuit board 2. An end portion of connection pattern 5 is arranged to be exposed from a side surface of resin portion 4, and the connection pattern 5 is electrically connected to shield film 6 in this exposing portion.

Next, a method for manufacturing conventional high-frequency module 1 will be described with reference to FIG. 11. FIG. 11 is a flowchart illustrating a method for manufacturing a conventional high-frequency module. In step S11, while a plurality of printed circuit boards 2 is coupled to one another, electronic component 3 is mounted on each of printed circuit boards 2. In step S12 subsequent to step S11, resin portion 4 is formed by transfer molding on the upper surface of printed circuit board 2 so as to cover electronic component 3. Resin 4A that forms resin portion 4 is a thermosetting resin.

In step S13 subsequent to step S12, a recess portion is formed in a position where printed circuit boards 2 are coupled together, and connection pattern 5 is exposed from the side surface of resin portion 4. In step S14 subsequent to step S13, conductive paste 6A is coated on the upper surface of resin portion 4 and is cured. At the same time, conductive paste 6A is also buried in the recess portion.

In step S15 subsequent to step S14, the coupling portion between printed circuit boards 2 is cut off. With this arrangement, high-frequency module 1 is completed.

In recent years, incorporating such high-frequency module 1 into mobile equipment has been progressing. Accordingly, a demand for a low-profile type of high-frequency module 1 has been increasing. Specifically, a thickness less than 1 mm including a thickness of printed circuit board 2 is demanded. An idea to meet such a demand includes reducing thicknesses of printed circuit board 2, resin portion 4, and electronic component 3, and mounting electronic component 3 with a face thereof placed downward.

However, since conventional high-frequency module 1 is formed by transfer molding, an internal stress (residual stress) tends to be caused in resin portion 4. When thickness of printed circuit board 2, resin portion 4, or electronic component 3 is reduced, deformation tends to be caused by the internal stress to printed circuit board 2, resin portion 4, electronic component 3, or the high-frequency module in its entirety. The internal stress is caused by various conditions such as flowability or ununiformity in the flow of resin 4A during transfer molding. The ununiformity becomes particularly noticeable when resin portions 4 are formed in a plurality of high-frequency modules 1 at one time, and different internal stresses are caused in individual high-frequency modules 1. In this way, since conventional high-frequency module 1 has a high-frequency circuit that is covered by resin portion 4, printed circuit board 2, resin portion 4, or electronic component 3 deforms, and sometimes deforms in a different degree. As a result, this may increase a variation in the characteristics of the high-frequency circuit. Particularly, when the high-frequency circuit is formed on printed circuit board 2, the influence exerted on the high-frequency module by the variation in the characteristics of the high-frequency circuit is very noticeable.

### SUMMARY

One example of the present disclosure relates to a method for manufacturing a high-frequency module.

The method for manufacturing a high-frequency module may includes the following steps:

placing a resin, which is in a non-flowable state, in a resin bath having an upper opening;

softening the resin in the resin bath until the resin becomes flowable;

placing, above the resin bath so as to close the upper opening, a substrate having a first surface on which an electronic component is mounted, with the electronic facing downward, and sucking air in a space formed between the substrate and the resin in the resin bath;

immersing the electronic component into the softened resin after the softening the resin and the sucking air in the space, and bringing the first surface of the softened resin;

pressurizing the softened resin and allowing the softened resin to flow into a gap between the resin substrate and the electronic component after the electronic component is immersed into the softened resin; and

curing the resin formed on the substrate and forming a resin portion on the substrate after the resin is allowed to flow into the gap.

The method may further include forming a metal film on a surface of the resin portion after the resin portion is formed. According to this method, an internal stress in the resin portion can be reduced, and a high-frequency module having a small variation in circuit characteristics can be realized.

### BRIEF DESCRIPTION OF DRAWINGS

FIG. 1 is a cross sectional view of a high-frequency module according to an exemplary embodiment of the present disclosure.

FIG. 2 is an exemplary flowchart illustrating a method for manufacturing the high-frequency module according to the exemplary embodiment of the present disclosure.

FIG. 3 is a schematic cross sectional view of a resin portion forming apparatus according to the exemplary embodiment of the present disclosure.

FIG. 4 is an exemplary flowchart illustrating a manufacturing method in a resin portion forming step according to the exemplary embodiment of the present disclosure.

FIG. 5 is a schematic cross sectional view of the resin portion forming apparatus and the high-frequency module under process in a resin substrate mounting step according to the exemplary embodiment of the present disclosure.

FIG. 6 is a schematic cross sectional view of the resin portion forming apparatus and the high-frequency module under process in an immersion step according to the exemplary embodiment of the present disclosure.

FIG. 7 is a schematic cross sectional view of the resin portion forming apparatus and the high-frequency module under process in a pressurized inflow step according to the exemplary embodiment of the present disclosure.

FIG. 8 is a cross sectional view of another high-frequency module according to the exemplary embodiment of the present disclosure.

FIG. 9 is an exemplary flowchart illustrating a method for manufacturing another high-frequency module according to the exemplary embodiment of the present disclosure.

FIG. 10 is an exemplary cross sectional view of a conventional high-frequency module.

FIG. 11 is a flowchart illustrating a method for manufacturing a conventional high-frequency module.

### DESCRIPTION OF EMBODIMENT

Hereinafter, a description will be given of high-frequency module 21 according to this exemplary embodiment.

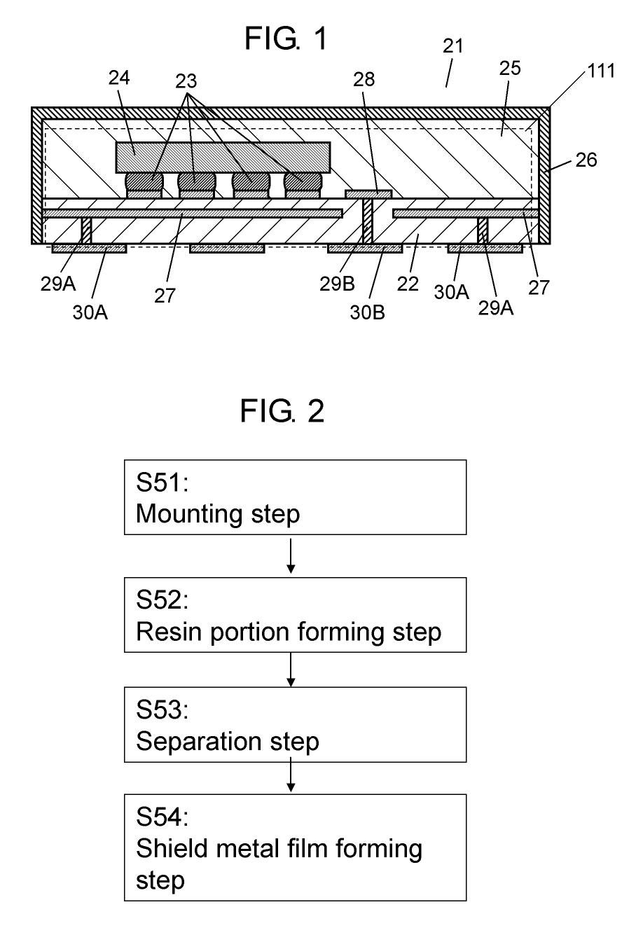

FIG. 1 is a cross sectional view of a high-frequency module according to the exemplary embodiment of the present disclosure. The high-frequency module includes, for example, resin substrate 22, electronic component 24 mounted on resin substrate 22, resin portion 25 formed on resin substrate 22 and burring therein electronic component 24, and shield metal film 26 covering a surface of resin portion 25.

Resin substrate 22 is a multilayer substrate made of a glass epoxy material. Resin substrate 22 is, for example, a four-layer substrate having a thickness of 0.2 mm. Electronic component 24 such as a semiconductor device or a chip part is mounted on resin substrate 22 by means of solder 23. The semiconductor device which is electronic component 24 is a chip-size package having a thickness of 0.35 mm, and is mounted with a face thereof placed downward on resin substrate 22 by flip-chip bonding through solder bumps. A pitch between the bumps is, for example, about 0.25 mm, a distance between the bumps is about 0.12 mm, and a gap between electronic component 24 and resin substrate 22 is about 0.12 mm. Further, a gap between the chip part and resin substrate 22 is about 0.08 mm if the chip part is mounted.

Electronic component 24 forms a high-frequency circuit 111 When electronic component 24 is mounted on resin substrate 22, a high-frequency circuit 111 (for example, Electronic tuner for TV, Electronic tuner for receiving FM broadcast, Transmitting and receiving module for cell phone, Bluetooth, WiFi, WILAN, or the like) is formed on resin substrate 22. a high-frequency circuit 111 transmits signals which range from, for example, 30 MHz to 6 GHz. Electronic component 24 according to this exemplary embodiment is connected to resin substrate 22 through solder bumps. However, electronic component 24 may be mounted on resin substrate 22 by forming stud bumps in electronic component 24 and using an anisotropic conductive film (ACF), an anisotropic conductive paste (ACP), a non-conductive film (NCF), a non-conductive paste (NCP), or the like.

Resin portion 25 is formed on the upper surface of resin substrate 22 and buries therein electronic component 24. Resin portion 25 is a thermosetting resin. Shield metal film 26 is formed to cover surfaces (upper surface and all four side surfaces) of resin portion 25.

Shield metal film 26 is a thin film formed by sputtering and having a thickness of, for example, about 1 μm, and is a very thin and dense film with little pinholes. Shield metal film 26 may be formed by plating or apply conductive paste. Shield metal film 26 formed by sputtering is durum and suitable for dumping high frequency signals. Shield metal film 26 is made of, for example, copper having excellent conductivity. Accordingly, shield metal film 26 has excellent shield performance, and therefore high-frequency module 21 is resistant to interference or the like.

Ground wiring pattern 27 is formed in resin substrate 22. Ground wiring pattern 27 is extended as far as to a peripheral portion of resin substrate 22, and an exposing portion of ground wiring pattern 27 is formed on a side surface of resin substrate 22. Ground wiring pattern 27 and shield metal film 26 are connected to each other at the exposing portion.

Referring to FIG. 1, although ground wiring pattern 27 is provided in an inner layer of resin substrate 22, it may be provided on the surface of the resin substrate (a portion making contact with resin portion 25). However, it is preferable to connect ground wiring pattern 27 and shield metal film 26 to each other by means of the inner layer. Since ground wiring pattern 27 is metallic, an adhesion force of ground wiring pattern 27 to resin portion 25 is small. Therefore, if the exposing portion of ground wiring pattern 27 is provided in the surface layer of resin substrate 22, peeling tends to be caused in an interface between ground wiring pattern 27 and resin portion 25 in separation step S53 which will be described later. By extending ground wiring pattern 27 from the inner layer of resin substrate 22, it is possible to reduce an occurrence of cracks or the like in shield metal film 26, even if the thickness of shield metal film 26 formed of a sputtered thin film is 1 μm. As a result, it is possible to realize high-frequency module 21 having excellent shield performance.

Ground wiring pattern 27 is connected to mounting pad 30A disposed on a bottom surface of resin substrate 22 through connection conductor 29A. Then, when high-frequency module 21 is mounted on a parent substrate (not illustrated), mounting pad 30A is connected to a ground wiring of the parent substrate. With this arrangement, the high-frequency circuit 111 formed on resin substrate 22 is surrounded by shield metal film 26 in upper and transverse directions thereof. Accordingly, it is possible to prevent a high-frequency signal that is processed (or generated) by the high-frequency circuit 111 from leaking outside, or to reduce a possibility in which a high-frequency noise generated outside jumps into the high-frequency circuit 111 in high-frequency module 21. As a result, it is possible to realize high-frequency module 21 resistant to electric interference.

Further, according to this exemplary embodiment, referring to FIG. 1, ground wiring pattern 27 is formed in the inner layer of resin substrate 22 below electronic component 24. With this arrangement, the high-frequency circuit 111 formed on resin substrate 22 is surrounded by ground wiring pattern 27 and shield metal film 26. As a result, it is possible to realize high-frequency module 21 having further resistant to electric interference.

Ground wiring pattern 27 is preferably not connected to the ground (not illustrated) of the high-frequency circuit 111. This means that the ground of the high-frequency circuit 111 is connected to ground terminal 28 on the surface of resin substrate 22, and is led to mounting pad 30B on the bottom surface of resin substrate 22 through connection conductor 29B that brings the upper and bottom surfaces of resin substrate 22 into conduction. In this way, the ground of the high-frequency circuit 111 and shield metal film 26 are separated in terms of high frequency (electrically). As a result, it is hardly possible that a high-frequency signal of the high-frequency circuit 111 is radiated outside from shield metal film 26, or a high-frequency noise that hops onto shield metal film 26 infiltrates into the high-frequency circuit 111.

Next, a method for manufacturing high-frequency module 21 will be described with reference to the drawings. FIG. 2 is a flowchart illustrating a method for manufacturing the high-frequency module according to the exemplary embodiment of the present disclosure.

In mounting step S51, electronic component 24 is mounted on resin substrate 22 while a plurality of resin substrates 22 is coupled together (as a main substrate), and the high-frequency circuit 111 is formed on resin substrate 22. Specifically, cream-based solder 23 is printed on the upper surface of resin substrate 22, and electronic component 24 is mounted thereon and soldered to resin substrate 22 by reflow soldering. The high-frequency circuit 111 is formed on a bottom surface side of electronic component 24, and electronic component 24 is mounted by flip-chip bonding in a direction in which a surface where the high-frequency circuit 111 is formed faces resin substrate 22 (in a face-down direction).

In mounting step S51, after mounting of electronic component 24 is completed, characteristics of the high-frequency circuit 111 are tested. In this test, a correction work may be performed on the circuit having characteristics outside a predetermined range. This correction may work involves replacing the part with another chip part having a different constant, trimming of a pattern inductor, or the like.

In resin portion forming step S52 subsequent to mounting step S51, resin portion 25 is formed on the upper surface of resin substrate 22. Resin 25A of a thermosetting type is used for resin portion 25 according to this exemplary embodiment.

In separation step S53 subsequent to resin portion forming step S52, coupled resin substrates 22 are separated into individual pieces using a rotating dicing blade. As a result, resin portion 25 formed on a coupling portion of resin substrate 22 and the coupling portion of resin substrate 22 are removed so that coupled resin substrates 22 are separated into individual resin substrates 22. Also, as a result of the cutting, the exposing portion of ground wiring pattern 27 is formed on a side surface of resin substrate 22.

In shield metal film forming step S54, a metal sputtered thin film is formed by metal sputtering as shield metal film 26 on a surface (upper and side surfaces) of resin portion 25 and side surfaces of resin substrate 22. As a result, shield metal film 26 is connected to ground wiring pattern 27 at the exposing portion of ground wiring pattern 27 provided on a side surface of resin substrate 22. Subsequent to shield metal film forming step S54, a final characteristic test may be performed on high-frequency module 21 so that high-frequency module 21 is completed.

According to the above-mentioned manufacturing method, shield metal film 26 is formed after separation step S53. For this reason, flaws are hardly caused by dicing in shield metal film 26. This is particularly effective when the film thickness of shield metal film 26 is small.

Next, resin portion forming step S52 will be described with reference to the drawings. First, resin portion forming apparatus 61 for forming resin portion 25 on resin substrate 22 will be described.

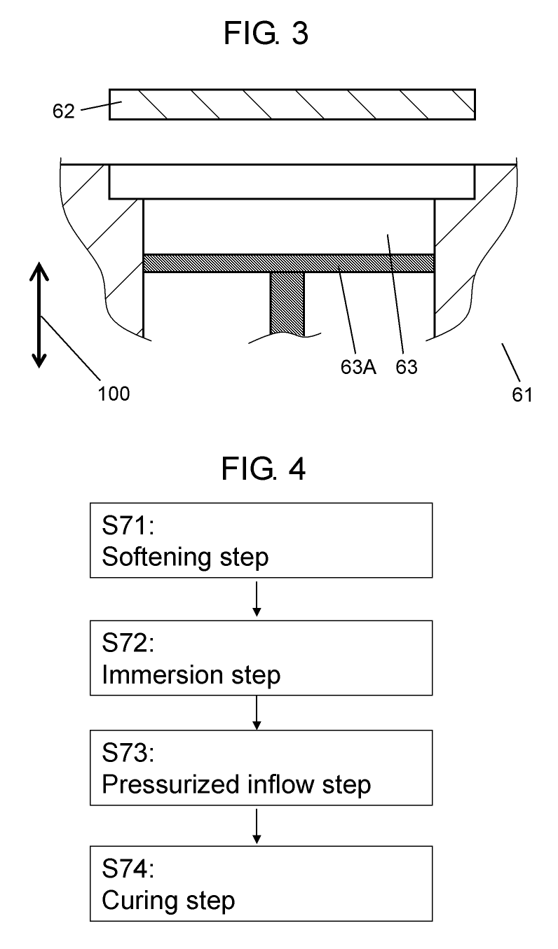

FIG. 3 is a schematic cross sectional view of resin portion forming apparatus 61 according to the exemplary embodiment of the present disclosure. Resin portion forming apparatus 61 may includes resin substrate mounting portion 62 and resin bath 63. Resin substrate 22 is mounted on resin substrate mounting portion 62. According to this exemplary embodiment, resin substrate 22 is mounted while electronic component 24 faces downward (i.e., in a direction in which electronic component 24 opposes resin bath 63). Resin substrate mounting portion 62 is structured to hold resin substrate 22 thereto.

Resin bath 63 having space in which resin 25A is thrown is provided below resin substrate mounting portion 62. Resin bath 63 may be movable in a vertical direction. In addition, bottom portion 63A of resin bath 63 may be independent from a movement of entire resin bath 63 and may be movable in a vertical direction (direction of an arrow 100 in FIG. 3) independently.

Heating portions (not illustrated) are individually provided in resin substrate mounting portion 62 and resin bath 63, and these heating portions individually heat resin substrate 22 and resin 25A. Further, resin portion forming apparatus 61 is provided with a compressor or the like. The compressor sucks air in resin bath 63 or between resin bath 63 and resin substrate mounting portion 62 so that formation of resin portion 25 can be performed substantially under vacuum.

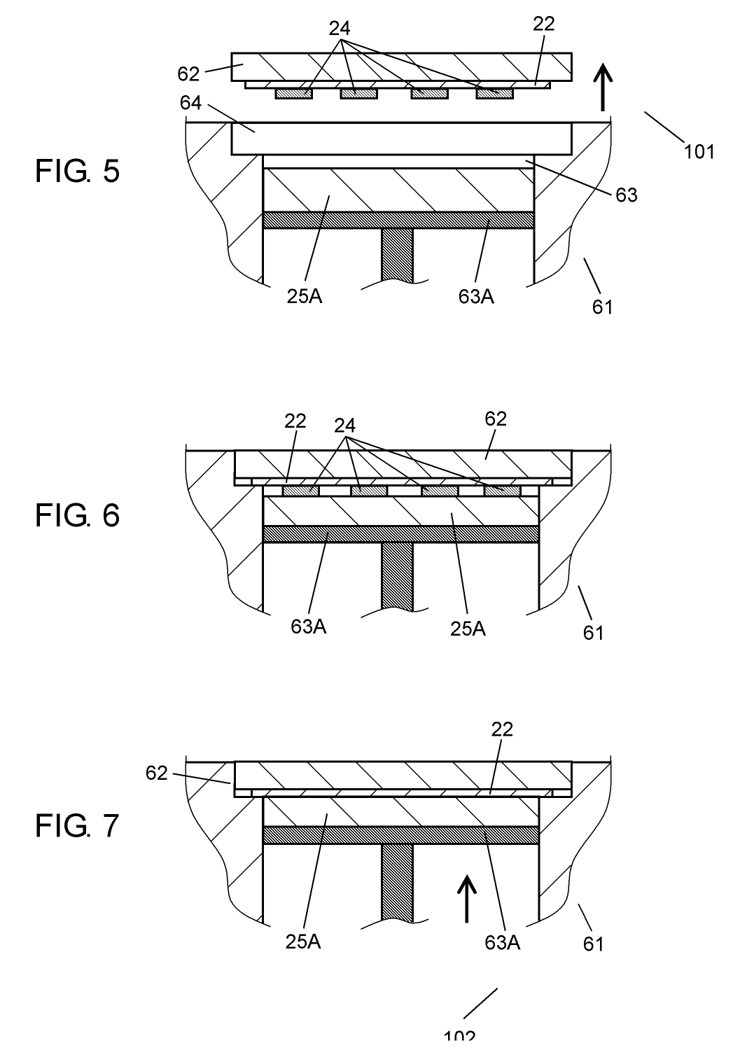

FIG. 4 is a flowchart illustrating a manufacturing method in resin portion forming step S52 according to the exemplary embodiment of the present disclosure. FIGS. 5 to 7 illustrate a manufacturing method in individual steps that form resin portion forming step S52. Resin portion forming step S52 using resin portion forming apparatus 61 will be described in detail in order of steps indicated in FIG. 4.

FIG. 5 is a schematic cross sectional view of the resin portion forming apparatus and the high-frequency module under process in a resin substrate mounting step according to the exemplary embodiment of the present disclosure. In FIGS. 4 and 5, in softening step S71 subsequent to mounting step S51, resin substrate 22 is mounted on resin substrate mounting portion 62 so that a mounting surface thereof on which electronic component 24 is mounted faces downward. In addition, resin 25A in a non-flowable state (unmelted and solid state, or gel state) is thrown into resin bath 63, and resin 25A is heated and softened until it becomes flowable. In parallel with this process, air in space 64 between resin 25A and resin substrate 22 may be sucked. The air is sucked until space 64 becomes substantially a vacuum state, and the suction of the air is stopped after resin 25A is completely melted. Since resin bath 63 and resin substrate mounting portion 62 have been heated in advance to a temperature at which resin 25A melts, it is possible to soften resin 25A in a short period of time.

Here, the process of sucking the air in space 64 may be performed either before or after the process of softening resin 25A to a flowable state. However, it is possible to shorten the time by performing these two processes in parallel with each other.

Resin 25A before being thrown into resin bath 63 is granular, and a predetermined amount of resin 25A measured by a measuring container is thrown into resin bath 63. Here, resin 25A is a thermosetting resin that does not exhibit fluidity at a temperature lower than a first temperature, exhibits fluidity in a range of temperature equal to or higher than the first temperature and lower than a second temperature, and is cured at a third temperature which is equal to or higher than the second temperature. Since resin 25A is granular when resin 25A is thrown into resin bath 63, it is possible to accurately measure an amount of resin 25A. It is also easy to automate the measurement and throwing.

Softening step S71 is performed according to the following procedure. Resin substrate mounting portion 62 and resin bath 63 are heated by the heating portions in advance so that a temperature of resin substrate mounting portion 62 and resin bath 63 becomes a temperature (first temperature) or higher at which resin 25A melts (exhibits fluidity) but a temperature lower than a temperature (second temperature) at which resin 25A cures. Resin 25A according to this exemplary embodiment is a thermosetting epoxy resin that exhibits smaller fluidity at a temperature lower than 140° C., is softened the most and exhibits fluidity at a temperature equal to or higher than 140° C. but lower than 175° C., and is cured at a third temperature equal to or higher than 175° C. Accordingly, the temperature of resin substrate mounting portion 62 and resin bath 63 is set to a temperature equal to or higher than 140° C. but lower than 175° C.

Resin substrate mounting portion 62 may be structured to slide in a horizontal direction in FIG. 3. When resin substrate mounting portion 62 slides, an area above resin bath 63 is opened. In this state, a specified amount of resin 25A is thrown from above resin bath 63. Immediately after resin 25A is thrown in this way, resin 25A starts to be heated.

In addition, since resin substrate mounting portion 62 opens an area therebelow by being slid, resin substrate 22 is absorbed onto a bottom surface of resin substrate mounting portion 62 while electronic component 24 is directed downward. Then, resin substrate mounting portion 62 slides again and stops at a position above resin bath 63. When throwing of resin 25A and mounting of resin substrate 22 are completed in this way, sucking air in space 64 is started to be sucked. Then, after resin 25A melts to become a complete flowable state, the suction is stopped, and the vacuum state at this moment is maintained.

In resin portion forming apparatus 61 according to this exemplary embodiment, resin substrate mounting portion 62 horizontally slides. However, resin bath 63 may slide instead. Further, at least one of resin substrate mounting portion 62 and resin bath 63 may be moved in a vertical direction. However, in this case, a distance between resin bath 63 and resin substrate mounting portion 62 is adjusted to be opened to such a degree that allows throwing operation of resin 25A and mounting operation of resin substrate 22.

FIG. 6 is a schematic cross sectional view of the resin portion forming apparatus and the high-frequency module under process in an immersion step according to the exemplary embodiment of the present disclosure. In immersion step S72 subsequent softening step 71, electronic component 24 is immersed in resin 25A that has been melted to a flowable state, and the bottom surface of resin substrate 22 is brought into contact with a liquid surface of molten resin 25A.

Specifically, while resin bath 63 and bottom portion 63A are moved upward (direction of an arrow 101 in FIG. 5) at speeds substantially equal to each other so that resin substrate 22 is held between resin bath 63 and resin substrate mounting portion 62. During this operation, it is necessary not to create a gap between resin bath 63 and resin substrate 22. For this purpose, it is preferable that a rubber gasket (not illustrated) or the like be provided at a position that makes contact with the bottom surface of resin substrate 22 in resin bath 63.

Then, after resin bath 63 ascends to a specified position (a position at which resin bath 63 makes contact with resin substrate 22), resin bath 63 is stopped. In this state, the liquid surface of resin 25A is arranged not to make contact with the bottom surface of resin substrate 22 yet. With this arrangement, a chance of resin 25A overflowing from resin bath 63 can be made smaller. However, at the same time, it is preferable that electronic component 24 be kept in contact with the liquid surface of resin 25A. By an action of surface tension of resin 25A, resin 25A creeps up along a side face of electronic component 24, or resin 25A infiltrates into a gap between electronic component 24 and resin substrate 22. As a result, in subsequent pressurized inflow step S73, resin 25A tends to be filled into a very narrow gap between electronic component 24 and resin substrate 22. In addition, bottom portion 63A continues its ascending even after the movement of resin portion 25 is stopped. As a result, the liquid surface of resin 25A makes contact with the bottom surface of resin substrate 22.

FIG. 7 is a schematic cross sectional view of the resin portion forming apparatus and the high-frequency module under process in a pressurized inflow step according to the exemplary embodiment of the present disclosure. When immersion step S72 completes, electronic component 24 looks like being completely immersed in resin 25A. However, there are some portions which are not filled with resin 25A in the gap between electronic component 24 and resin substrate 22.

To cope with this, pressurized inflow step S73 is performed after immersion step S72. In pressurized inflow step S73, resin 25A is pressurized (in a direction of an arrow 102 in FIG. 7), and resin 25A is allowed to flow into unfilled gaps forcibly by the pressure. At this point, space surrounded by resin bath 63 and resin substrate 22 is filled with resin 25A with exceptions of unfilled very narrow gaps between semiconductor 24 and resin substrate 22. Accordingly, when resin 25A is pressurized, bottom portion 63A hardly ascends, and only the pressure of resin 25A increases. Then, the pressurization is continued until such a pressure reaches a specified value, and that pressure is maintained. In pressurized inflow step S73, it is important to adjust the temperature of resin 25A at a temperature equal to or higher than the first temperature but lower than the second temperature. With this arrangement, resin 25A is reliably filled into the very narrow gaps between electronic component 24 or the chip part and resin substrate 22.

In this exemplary embodiment, solder 23 is tin and silver based lead-free solder, and melting point thereof is about 200° C. Since the melting point of solder 23 is set to a temperature equal to or higher than the second temperature, solder 23 does not melt in pressurized inflow step S73. Accordingly, an electric link between electronic component 24 and resin substrate 22 is hardly disconnected.

In curing step S74 subsequent to pressurized inflow step S73, resin 25A is further heated until the temperature thereof reaches the third temperature equal to or higher than the second temperature so that resin 25A cures. As a result, resin portion 25 is formed on resin substrate 22. In curing step S74, it is preferable to maintain the pressure that is applied in pressurized inflow step S73 at least during a period until the fluidity of resin 25A ceases to exist. With this arrangement, voids or the like are hardly left in the gap between electronic component 24 and resin substrate 22.

According to the manufacturing method described above, since a pressure is applied in pressurized inflow step S73, resin 25A is reliably filled into a very narrow gap between electronic component 24 and resin substrate 22. In addition, since a pressure is applied to electronic component 24 only in pressurized inflow step S73, this can reduce a stress exerted on electronic component 24. Therefore, deformation of electronic component 24 or resin substrate 22 becomes smaller. As a result of this, variations in a distance between the high-frequency circuit 111 and shield metal film 26, a distance between the high-frequency circuit 111 and resin substrate 22, further, a distance between resin substrate 22 and shield metal film 26, or the like can be made smaller. Consequently, variations in stray capacitance values therebetween can be made smaller, and therefore high-frequency module 21 having small variations can be realized.

In addition, electronic component 24 is merely immersed in immersion step S72, and resin 25A is caused to flow in pressurized inflow step S73. Therefore, a distance in which resin 25A flows is very small as compared with that of the transfer molding. Accordingly, the internal stress caused by ununiformity in the flow of resin 25A or the like after resin 25A cures can be also made smaller. This makes it possible to reduce a strain (deformation) of electronic component 24, resin substrate 22, and resin portion 25 themselves. Accordingly, variations in the stray capacitance values can be made smaller. As a result, it is possible to realize high-frequency module 21 having a small variation in the characteristics of the high-frequency circuit 111.

According to this exemplary embodiment, in particular, since electronic component 24 is mounted with a face thereof placed downward by flip-chip bonding, a clearance between electronic component 24 and resin substrate 22 is very small. This causes a large stray capacitance between the high-frequency circuit 111 formed in electronic component 24 and ground wiring pattern 27. A variation in this stray capacitance exerts a great influence on the characteristics of the high-frequency circuit 111 of electronic component 24. This is a very important issue in burying the high-frequency circuit 111 in resin 25A. To state it differently, even the high-frequency circuit 111 that has passed the test of high-frequency characteristics in mounting step S51 may fail a test conducted after resin portion 25 is formed, if the strain of electronic component 24, resin substrate 22, or resin portion 25 itself is large. However, once the resin portion 25 is formed, a repairing work is very difficult, and there is no other way but to discard the product, which may greatly worsen the yield. To cope with this, a distance in which resin 25A flows is made smaller by using the manufacturing method according to this exemplary embodiment to thereby reduce the residual stress remaining in resin 25A, and reduce the stress exerted on electronic component 24, resin substrate 22, or resin portion 25 itself. With this arrangement, it is possible to reduce a variation in the high-frequency characteristics after resin portion 25 is formed, and realize high-frequency module 21 with high yield.

Further, reducing the residual stress exerts a great influence on reliability of the characteristics of high-frequency module 21 over a long period. It is considered that expansion and contraction are caused in resin portion 25 or resin substrate 22 by a change in temperature or the like, and this may change an internal stress distribution inside resin portion 25. For this reason, an amount of strain of electronic component 24, resin substrate 22, resin portion 25, or the like changes. As a result, values of the stray capacitances between electronic component 24, and resin substrate 22, ground wiring pattern 27, and shield metal film 26 may change from the values during manufacturing. To cope with this, by reducing the internal stress by the above-mentioned manufacturing method, it is possible to realize high-frequency module 21 that can maintain the stable characteristics over a long period of time also against a change in temperature or the like.

Since resin 25A is forcibly filled into the gap in pressurized inflow step S73, it is also possible to reliably fill resin 25A into the gap between electronic component 24 and resin substrate 22 as compared with a printing method or a method by potting. Accordingly, it is possible to realize high-frequency module 21 extremely excellent in reliability.

As described above, according to the exemplary embodiment, since it is possible to reduce a chance of destroying electronic component 24 or the chip part by a compression pressure and reduce deformation of electronic component 24, the thickness of electronic component 24 can be made smaller. For this reason, even if the thickness of resin portion 25 that is formed above electronic component 24 or the chip part is small, resin portion 25 can be reliably formed above electronic component 24 or the chip part as compared with the case of conventional transfer molding. This is because resin portion 25 above electronic component 24 is formed by immersion in immersion step S72. With this arrangement, a low-profile high-frequency module 21 can be realized. According to this exemplary embodiment, high-frequency module 21 having a thickness of 0.8 mm is produced.

High-frequency module 21 having a thickness of 0.5 mm can also be produced in addition to the foregoing. In this high-frequency module 21, resin substrate 22 has a thickness of 0.1 mm, and electronic component 24 has a thickness of 0.25 mm. Although the thicknesses are very small, deformation is also small, and the variation in the characteristics is also small. Further, although a gap between electronic component 24 and resin substrate 22 is 0.08 mm which is very narrow, resin 25A is reliably filled into this gap. Moreover, although the thickness of resin portion 25 above electronic component 24 is 0.07 mm which is very thin, resin portion 25 having a stable thickness is formed.

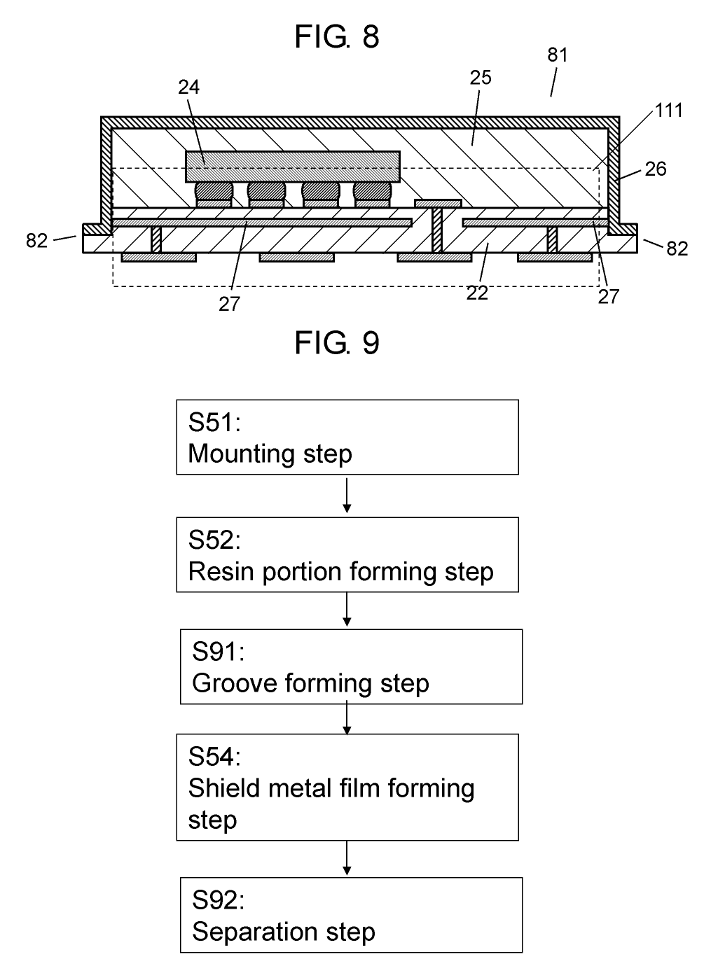

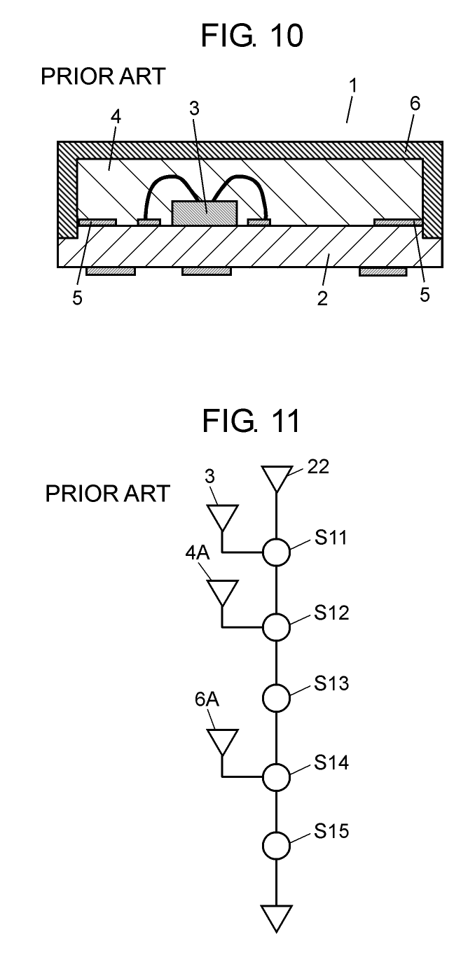

Next, another high-frequency module according to this exemplary embodiment is described with reference to the drawings. FIG. 8 is a cross sectional view of another high-frequency module 81 according to this exemplary embodiment of the present disclosure.

According to high-frequency module 21 illustrated in FIG. 1, the side surface of resin substrate 22 and the side surface of resin portion 25 are in line with each other, and shield metal film 26 is extended and formed as far as to a lower end of the side surface of resin substrate 22. In contrast, high-frequency module 81 is different from high-frequency module 21 in the respect that step portion 82 is formed in a lower portion of the side surface of resin substrate 22, and shield metal film 26 is formed as far as to an upper end of step portion 82 on the side surface of resin substrate 22. A portion on an upper side of step portion 82 on the side surface of resin substrate 22 is in line with the side surface of resin portion 25, and the exposing portion of ground wiring pattern 27 is also formed above step portion 82 on the side surface of resin substrate 22.

Next, a method for manufacturing high-frequency module 81 will be described with reference to the drawings. FIG. 9 is a flowchart illustrating a method for manufacturing high-frequency module 81. In FIG. 9, steps identical with those illustrated in FIG. 2 are identified with the same reference numerals as those used in FIG. 2, and descriptions thereof will be simplified. In FIG. 9, the steps up to resin portion forming step S52 are the same as those of the method for manufacturing high-frequency module 21. Groove forming step S91 is performed subsequent to resin portion forming step S52. In groove forming step S91, resin substrates 22 are not cut into individual pieces but remain with the high-frequency modules being coupled together and with the coupling portions of resin substrate 22 being left intact. In this state, a groove is formed in resin portion 25 and resin substrate 22 in the coupling portion so that the exposing portion of ground wiring pattern 27 is exposed from the side surface of resin substrate 22.

After groove forming step S91, shield metal forming step S54 is performed. Shield metal film 26 is formed in the groove formed on a periphery (upper and side surfaces) of resin portion 25 and resin substrate 22 (upper surface of the step portion 82 and side surface of resin substrate 22). Then, after shield metal film forming step S54, separation step S92 is performed. In separation step S92, the coupling portion of resin substrates 22 is cut so as to be smaller than a width of the groove by a rotating dicing blade or the like having a blade thickness smaller than the width of the groove. With this arrangement, flaws are hardly caused in shield metal film 26 in separation step S92. As a result an excellent shield can be realized. According to this exemplary embodiment, shield metal film forming step S54 can be performed while resin substrates 22 are coupled together. In addition, if a step of the characteristic test is conducted between shield metal film forming step S54 and separation step S92, the test can also be conducted while resin substrates 22 are coupled together, and therefore the productivity becomes excellent. Further, as the shield metal film forming method, a vacuum deposition method, an ion plating method, a physical vapor deposition method, a CVD (Chemical Vapor Deposition) method, or the like may be used other than the sputtering method.

### INDUSTRIAL APPLICABILITY

The high-frequency module according to the present disclosure provides an effect of smaller variation in characteristics thereof when the module is reduced in thickness, and is useful as a high-frequency module to be incorporated in portable electronic equipment or the like.

### REFERENCE MARKS IN THE DRAWINGS

21, 81 High-frequency module
22 Resin substrate
23 Solder
24 Electronic component
25 Resin portion
25A Resin
26 Shield metal film
28 Ground terminal
27 Ground wiring pattern
29A, 29B Connection conductor
30A, 30B Mounting pad
61 Resin portion forming apparatus
62 Resin substrate mounting portion
63 Resin bath
63A Bottom portion
64 Space
82 Step portion
100, 101, 102 Arrow
111 high-frequency circuit

1. A method for manufacturing a high-frequency module, the method comprising steps of:
placing a resin, which is in a non-flowable state, in a resin bath having an upper opening;
softening the resin in the resin bath until the resin becomes flowable;
placing, above the resin bath so as to close the upper opening, a substrate having a first surface on which a high frequency circuit including an electronic component is disposed, with the electronic component facing downward, and sucking air in a space formed between the substrate and the resin in the resin bath;
immersing the electronic component into the softened resin after the softening the resin and the sucking air in the space, and bringing the first surface of the substrate into contact with a liquid surface of the softened resin;
pressurizing the softened resin and allowing the softened resin to flow into a gap between the substrate and the electronic component after the electronic component is immersed into the softened resin;
curing the resin formed on the substrate and forming a resin portion on the substrate after the resin is allowed to flow into the gap; and
forming a shield metal film on a surface of the resin portion after the resin portion is formed.

2. The method of claim 1, wherein the shield metal film is formed by sputtering.

3. The method for manufacturing a high-frequency module according to claim 1,
wherein the step of softening of the resin and the step of sucking of air in the space are performed in parallel with each other.

4. The method for manufacturing a high-frequency module according to claim 1, wherein:
the resin is a thermosetting resin that does not have fluidity at a temperature lower than a first temperature, has fluidity in a temperature range equal to or higher than the first temperature and lower than a second temperature which is higher than the first temperature, and cures at a third temperature which is equal to or higher than the second temperature, and
in the step of pressurizing the softened resin and allowing of the resin to forcibly flow into the gap, a temperature of the resin is kept in the temperature range.

5. The method for manufacturing a high-frequency module according to claim 4,
wherein the electronic component and the substrate are connected by solder having a melting point equal to or higher than the second temperature.

6. The method for manufacturing a high-frequency module according to claim 4,
wherein, in the step of curing of the resin, the resin is heated until a temperature of the resin reaches the third temperature or higher while a pressure is applied to the resin.

7. The method for manufacturing a high-frequency module according to claim 1,
wherein the electronic component includes a semiconductor device.

8. A method for manufacturing a high-frequency module, the method comprising steps of:
placing a resin, which is in a non-flowable state, in a resin bath having an upper opening;
softening the resin in the resin bath until the resin becomes flowable;
placing, above the resin bath so as to close the upper opening, a main substrate having a first surface on which high frequency circuits including a plurality electronic components are disposed, with the plurality electronic components facing downward, and sucking air in a space formed between the main substrate and the resin in the resin bath;
immersing the plurality electronic components into the softened resin after the softening the resin and the sucking air in the space, and bringing the first surface of the main substrate into contact with the softened resin;
pressurizing the resin and allowing the resin to flow into a gap between the main substrate and the plurality electronic components after the plurality electronic components is immersed into the softened resin;
curing the resin and forming a resin portion on the main substrate after the resin is allowed to flow into the gap;
cutting the main substrate into a plurality of modules each including one of the high frequency circuits; and
forming a shield metal film on a surface of the resin portion after the resin portion is formed.

9. The method of claim 8, wherein:
each of the modules includes a ground wiring pattern,
after the step of cutting the ground wiring patter is exposed at a side surface of each of the module, and
in the step of forming a shield metal film, the shield metal film is connected to the ground wiring pattern.

10. The method of claim 9,
wherein, after the step of forming of the shield metal film, the main substrate is cut.

11. The method of claim 9, further comprising, before the step of cutting, a step of:
forming a groove in a main resin portion and the main substrate at a portion to be cut so that the ground wiring pattern exposes from a side surface of each of the modules before cutting, wherein, in the step of forming a shield metal film, the shield metal film connects the ground wiring pattern, and
in the step of cutting, the main substrate is cut together with the shield metal film at a width smaller than a width of the groove.

12. The method of claim 8,
wherein the electronic component includes a semiconductor device.

13. A high-frequency module including:
a substrate including a first surface;
a high frequency circuit including an electronic component mounted on the first surface of the substrate;
a ground wiring pattern;
a resin portion burying the electronic component therein and formed at least on the first surface of the substrate; and
a shield metal film covering a surface of the resin portion,
wherein the ground wiring pattern is embedded in the substrate and connected to the shield metal film at a side surface of the substrate.

14. The high-frequency module of claim 13, wherein:
the side surface of the substrate has a step including a vertical face and horizontal face, and
the ground wiring pattern is connected to the shield metal file at the vertical face.

15. The module of claim 13, wherein:
the module includes another ground wiring pattern connected to the electronic component, and
the ground wiring pattern and the another ground wiring patter are not physically connected.

16. The module of claim 15, wherein:
the ground wiring pattern is disposed at least below the electronic component, and
the other ground wiring pattern is not disposed below the electronic component.
